(19) United States
(12) Patent Application Publication
(10) Pub. No.: US 2005/0159011 A1
(43) Pub. Date: Jul. 21, 2005

(54) Selective etching silicon nitride

(76) Inventors: Vani K. Thirumala, San Jose, CA (US); Nabil G. Mistkawi, Keizer, OR (US); Bruce E. Beattie, Portland, OR (US); John W. O'Sullivan, CO. Weath (IE); Huiying Liu, Sunnyvale, CA (US); Noriko Oshiro, San Jose, CA (US); Hokkin Choi, San Jose, CA (US); Loretta Cordrey, Livermore, CA (US)

Correspondence Address: TROP PRUNER & HU, PC, 8554 KATY FREEWAY, SUITE 100, HOUSTON, TX, 77024, US

(21) Appl. No.: 10/761,392

(22) Filed: Jan. 21, 2004

(51) Int. Cl. H01L 21/302; H01L 21/461

(52) U.S. Cl. 438/745

(57) ABSTRACT

By providing a silicon containing precursor, such as methyl triethoxysilane, to a phosphoric etch bath, wafers containing nitride may be selectively etched without unduly impacting other silicon containing underlying layers.

### BACKGROUND

This invention relates generally to the manufacture of semiconductor integrated circuits and, particularly, to processes for selectively etching silicon nitride.

In a variety of semiconductor manufacturing processes it is desirable to etch silicon nitride. For example, silicon nitride etching may occur in connection with forming silicon nitride diffusion barriers, masking layers for local oxidation of silicon and high dielectric constant insulators, as a few examples. Commonly, the silicon nitride must be etched without significantly etching an adjacent or underlying silicon dioxide or other silicon containing layers.

Conventionally, there is a problem because the silicon nitride etch reaction produces a substantial amount of silicon in the form of silicic acid. Thus, conventionally, a source of silicon in the form of a test wafer is added to a bath of the phosphoric acid etching solution.

While the use of test wafers is an effective source of silicon for making silicic acid, a large number of test wafers may be consumed. As a result, the cost of the process may be adversely impacted. Also, the use of test wafers as a source of silicic acid for the etch bath is time consuming.

Thus, there is a need for better ways to selectively etch silicon nitride.

### BRIEF DESCRIPTION OF THE DRAWINGS

FIG. 1 is a schematic depiction of wafer in accordance with one embodiment of the present invention; and

FIG. 2 is a process flow in accordance with one embodiment of the present invention.

### DETAILED DESCRIPTION

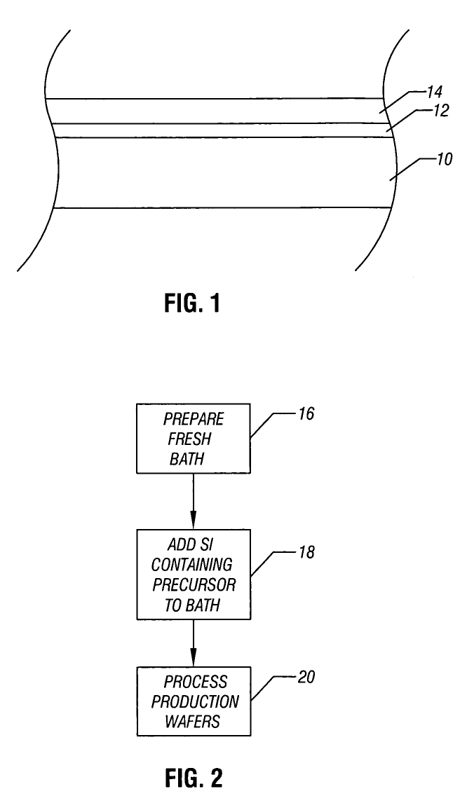

Referring to FIG. 1, a silicon wafer may be covered with a silicon dioxide layer and a silicon nitride layer. The etch may be selective to remove the silicon nitride without unduly removing either silicon dioxide or other silicon containing underlying layers.

The wet etching of silicon nitride proceeds as follows:
3Si₃N₄+27H₂O+4H₃PO₄═4(NH₄)₃PO₄+9H₂SiO₃
The formation of silicic acid (H₂SiO₃) involves nine silicon atoms per three molecules of silicon nitride, making the reaction highly dependent on having plenty of silicon atoms.

A silicon precursor in the form of a liquid may be added to the etch bath used to selectively etch silicon nitride in one embodiment. For example, a silane or siloxane containing compound, such as methyl triethoxysilane (MTEOS), may be added as a source of silicic acid. In one embodiment, the silicon containing precursor may be added to an 80 percent phosphoric bath to load the bath with silicic acid. This leads to a conditioned bath from the start and results in the desired selectivity of the nitride to oxide etch rate.

Thus, initially a fresh bath of 80 percent phosphoric acid may be used. An appropriate amount of silicon containing precursor is added to the bath to condition the bath to obtain about 100 to about 1000 parts per million of silicon. Then the wafers may be processed through the bath to selectively etch the silicon nitride. The wafers to be etched and the silicon containing precursor may be added simultaneously.

In one embodiment, the nitride coated wafers may be etched for 30 to 90 minutes in 180 milliliters of 80% phosphoric acid with from about 0.6 to about 2 milliliters of MTEOS at approximately 160° C.

While the present invention has been described with respect to a limited number of embodiments, those skilled in the art will appreciate numerous modifications and variations therefrom. It is intended that the appended claims cover all such modifications and variations as fall within the true spirit and scope of this present invention.

1. A method comprising:
adding a liquid silicon containing precursor to an etch bath for silicon nitride etching; and
etching silicon nitride on a wafer.

2. The method of claim 1 including adding a silane as the silicon containing precursor.

3. The method of claim 2 including adding methyl triethoxysilane.

4. The method of claim 3 including adding methyl triethoxysilane to a heated bath of phosphoric acid.

5. The method of claim 4 including adding about 0.6 to about 2 milliliters of methyl triethoxysilane to a phosphoric acid etch bath.

6. The method of claim 1 including adding a siloxane as the silicon containing precursor.

7. The method of claim 1 including adding a silicon containing precursor to the etch bath to obtain between about 100 and about 1000 parts per million of silicon in the etch bath.

8. A method comprising:
adding methyl triethoxysilane to an etch bath for silicon nitride etching; and
etching silicon nitride on a wafer.

9. The method of claim 8 including adding methyl triethoxysilane to a heated bath of phosphoric acid.

10. The method of claim 9 including adding about 0.6 to about 2 milliliters of methyl triethoxysilane to a phosphoric acid etch bath.

11. The method of claim 8 including adding methyl triethoxysilane to the etch bath to obtain between about 100 and about 1000 parts per million of silicon in the etch bath.

12. A method comprising:
simultaneously adding wafers having a silicon nitride layer to be etched and a source of silicon to a nitride etching bath.

13. The method of claim 12 including adding a silane as a source of silicon.

14. The method of claim 12 including adding a siloxane as a source of silicon.

15. The method of claim 12 including adding triethoxysilane to the etch bath.

16. The method of claim 12 including adding a silicon containing precursor to the etch bath to obtain between 100 and 1000 parts per million of silicon in the etch bath.

17. The method of claim 12 including adding a liquid silicon containing precursor to said etch bath.
